(19) United States
(12) Patent Application Publication
(10) Pub. No.: US 2026/0305039 A1
(43) Pub. Date: Oct. 1, 2026

(54) ELECTRONIC DEVICE AND METHOD FOR MANUFACTURING THE SAME

(71) Applicant: InnoLux Corporation, Miao-Li County (TW)

(72) Inventors: Chun-Kai LEE, Miao-Li County (TW); Cheng-Hsu Chou, Miao-Li County (TW); Fang-ly Wu, Miao-Li County (TW)

(73) Assignee: InnoLux Corporation, Miao-Li County (TW)

(21) Appl. No.: 19/564,214

(22) Filed: Mar. 12, 2026

(30) Foreign Application Priority Data
Mar. 31, 2025 (CN) 202510386872.4

(51) Int. Cl. H10H 29/854; H10H 29/01; H10H 29/24; H10K 59/80; H10K 59/95

(52) U.S. Cl. CPC H10H 29/854; H10H 29/0362; H10H 29/24; H10K 59/873; H10K 59/95

(57) ABSTRACT

An electronic device includes a substrate, a light-emitting unit and a first encapsulation layer. A surface of the substrate defines a normal direction. The light-emitting unit is disposed on the substrate. A first encapsulation layer is disposed on the light-emitting unit. The first encapsulation layer includes a plurality of first magnetic particles. The first encapsulation layer has different magnetic particle concentrations in a horizontal direction perpendicular to the normal direction.

### BACKGROUND OF THE DISCLOSURE

### 1. Field of the Disclosure

The present disclosure relates to an electronic device and a method for manufacturing the same, and more particularly, to an electronic device that is advantageous for enhancing the fastening strength of electronic components and a method for manufacturing the same.

### 2. Description of the Prior Art

The fastening strength of electronic components is critical to the durability and the reliability of an electronic device. In existing technology, electronic components are typically fixed to a substrate by soldering, adhesives, or encapsulation materials. However, the fastening strength provided by these methods may be insufficient in certain application environments, resulting in displacement or detachment of the electronic components when subjected to vibration or impact.

### SUMMARY OF THE DISCLOSURE

According to an embodiment of the present disclosure, an electronic device includes a substrate, a light-emitting unit and a first encapsulation layer. A surface of the substrate defines a normal direction. The light-emitting unit is disposed on the substrate. A first encapsulation layer is disposed on the light-emitting unit. The first encapsulation layer includes a plurality of first magnetic particles. The first encapsulation layer has different magnetic particle concentrations in a horizontal direction perpendicular to the normal direction.

According to another embodiment of the present disclosure, a method for manufacturing an electronic device includes steps as follows. A substrate is provided. A surface of the substrate defines a normal direction. A light-emitting unit is provided to be disposed on the substrate. A first encapsulation layer is provided to be disposed on the light-emitting unit. The first encapsulation layer includes a plurality of magnetic particles, and the first encapsulation layer has different magnetic particle concentrations in a horizontal direction perpendicular to the normal direction.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic top view of an electronic device according to a first embodiment of the present disclosure.

FIG. 2 is a partial cross-sectional schematic view of the electronic device shown in FIG. 1.

FIG. 3 is a partial cross-sectional schematic view of an electronic device according to a second embodiment of the present disclosure.

FIG. 4 is a partial cross-sectional schematic view of an electronic device according to a third embodiment of the present disclosure.

FIG. 5 is a partial cross-sectional schematic view of an electronic device according to a fourth embodiment of the present disclosure.

FIG. 6 is a schematic top view of an electronic device according to a fifth embodiment of the present disclosure.

FIG. 7 is a schematic bottom view of the electronic device shown in FIG. 6.

FIG. 8 is an exploded schematic view of the electronic device shown in FIG. 7.

FIG. 9 is a flowchart illustrating steps of a method for manufacturing an electronic device according to one embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms "include/comprise" and "have" are used in an open-ended fashion, and thus should be interpreted to mean "include, but not limited to...".

In the present disclosure, the directional terms, such as "on/up/above", "down/below", "front", "rear/back", "left", "right", etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, when a structure (or layer, or component, or substrate) is described as located on/above another structure (or layer, or component, or substrate), it may refer that the two structures are adjacent and directly connected to each other, or the two structures are adjacent and indirectly connected to each other. The two structures being indirectly connected to each other may refer that at least one intervening structure (or intervening layer, or intervening component, or intervening substrate, or intervening interval) exists between the two structures, a lower surface of one of the two structure is adjacent or directly connected to an upper surface of the intervening structure, and an upper surface of the other of the two structures is adjacent or directly connected to a lower surface of the intervening structure. The intervening structure may be a single-layer or multi-layer physical structure or a non-physical structure, and the present disclosure is not limited thereto. In the present disclosure, when a certain structure is disposed "on/above" other structures, it may refer that the certain structure is "directly" disposed on/above the other structures, or the certain structure is "indirectly" disposed on/above the other structures, i.e., at least one structure is disposed between the certain structure and the other structures.

The terms "equal", "identical/the same", or "substantially/approximately" mentioned in this document generally mean being within 20% of a given value or range, or being within 10%, 5%, 3%, 2%, 1% or 0.5% of the given value or range.

Furthermore, any two values or directions used for comparison may have a certain error. If a first value is equal to a second value, it implies that there may be an error of about 10% between the first value and the second value; if a first direction is perpendicular or "substantially" perpendicular to a second direction, then an angle between the first direction and the second direction may be between 80 degrees to 100 degrees; if the first direction is parallel or "substantially" parallel to the second direction, an angle between the first direction and the second direction may be between 0 degree to 10 degrees.

Although ordinal numbers such as "first", "second", etc., may be used to describe components in the description and the claims, it does not imply and represent that there have other previous ordinal number. The ordinal numbers do not represent the order of the components or the manufacturing order of the components. The ordinal numbers are only used for discriminate a component with a certain designation from another component with the same designation. The claims and the description may not use the same terms. Accordingly, a first component in the description may be a second component in the claims.

In addition, the term "a given range is from a first value to the second value" or "a given range falls within a range from a first value to a second value" refers that the given range includes the first value, the second value and other values therebetween.

Moreover, the electronic device of the present disclosure may be applied to a display device, a backlight device or a sensing device, but is not limited thereto. The display device may be a non-self-luminous type display device or a self-luminous type display device. The sensing device may be a device for sensing capacitance, light, thermal or ultrasonic, but is not limited thereto. The electronic components of the electronic device may include passive components and active components, such as capacitors, resistors, inductors, diodes and transistors. The diode may include a light emitting diode (LED) or a photodiode. The light emitting diode may include organic light emitting diode (OLED), mini LED, micro LED or quantum dot LED, but is not limited thereto. Furthermore, the electronic devices may be foldable or flexible electronic devices. The electronic device may be any combination of aforementioned devices, but is not limited thereto. Furthermore, a shape of the electronic device may be a rectangle, a circle, a polygon, a shape with curved edge or other suitable shapes. The electronic device may have peripheral systems, such as a driving system, a control system and a light system for supporting the display device.

In the present disclosure, it should be understood that a depth, a thickness, a width or a height of each component, or a spacing distance or a distance between components may be measured by an optical microscopy (OM), a scanning electron microscope (SEM), a film thickness profiler (α-step), an ellipsometer or other suitable methods. In some embodiments, a cross-sectional image including components to be measured can be obtained by the SEM, and the depth, the thickness, the width or the height of each component, or the spacing distance or the distance between components can be measured thereby.

It should be noted that the technical features in different embodiments described in the following can be replaced, recombined, or mixed with one another to constitute another embodiment without departing from the spirit of the present disclosure.

Unless otherwise defined, all terms (including technical and scientific terms) used herein have the same meaning as commonly understood by a person having ordinary skill in the art to which the present disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the terms “electrically connected” or “coupled” include any direct or indirect electrical connection means.

In the present disclosure, for ease of explanation, some drawings are described with reference to an XYZ Cartesian coordinate system, in which the direction Z may, for example, be parallel to a normal direction of the substrate of the electronic device.

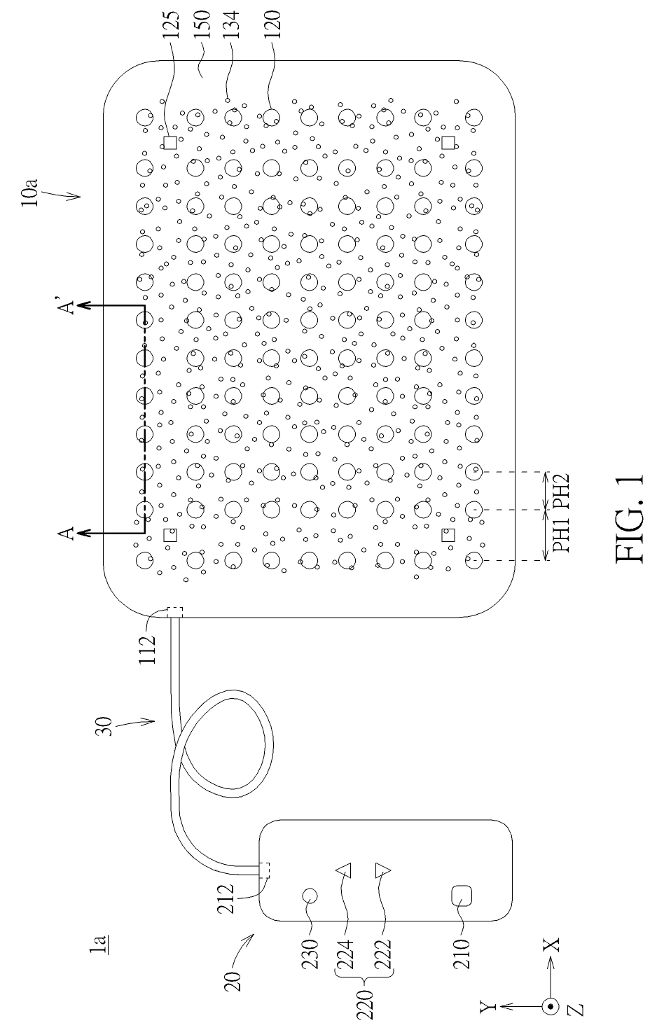

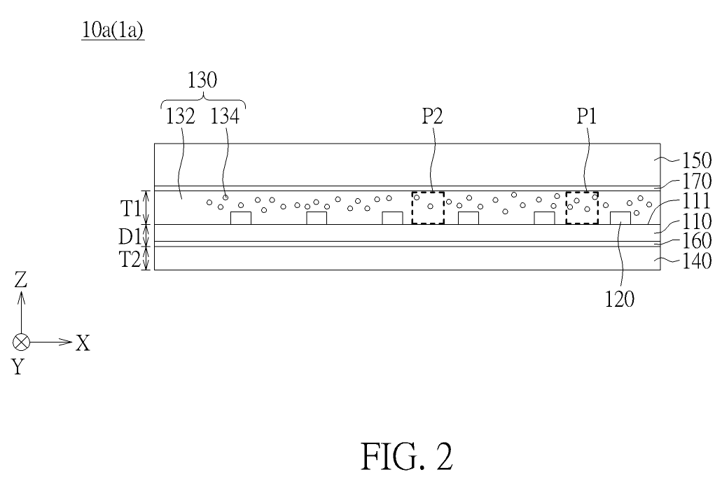

Please refer to FIGS. 1 and FIG. 2. FIG. 1 is a schematic top view of an electronic device 1a according to a first embodiment of the present disclosure. FIG. 2 is a partial cross-sectional schematic view of the electronic device 1a shown in FIG. 1. Specifically, FIG. 2 is a cross-sectional schematic view of the electronic device 1a shown in FIG. 1 taken along line A–A’. The electronic device 1a may include a main body 10a. The main body 10a may be, for example, a bendable, foldable, rollable, or stretchable main body. For example, the electronic device 1a may be a phototherapy device, and the main body 10a may be a phototherapy patch. With the main body 10a being bendable, foldable, rollable, or stretchable, it is advantageous for the main body 10a conforming to a portion of a human body (not shown, hereinafter also referred to as a phototherapy portion) which is required to be improved via the phototherapy patch. However, the present disclosure is not limited thereto.

The main body 10a includes a substrate 110, light-emitting units 120, and an encapsulation layer 130. A surface 111 of the substrate 110 defines a normal direction (e.g., the direction Z), and the light-emitting units 120 are disposed on the substrate 110. The encapsulation layer 130 is disposed on the light-emitting units 120. The encapsulation layer 130 includes a plurality of magnetic particles 134, and the encapsulation layer 130 has different magnetic particle concentrations in a horizontal direction (e.g., the direction X), and the horizontal direction is perpendicular to the normal direction. As shown in FIG. 2, the encapsulation layer 130 may include a portion P1 and a portion P2 arranged along the horizontal direction, and a magnetic particle concentration of the portion P1 is greater than that of the portion P2. However, according to the present disclosure, the positions of the portions P1 and P2 of the encapsulation layer 130 with different magnetic particle concentrations are not limited to that shown in FIG. 2. With the encapsulation layer 130 including the magnetic particles 134, the fastening strength of the electronic components (e.g., the light-emitting units 120) on the substrate 110 can be enhanced by the magnetic force of the magnetic particles 134. Thereby, the durability and/or the reliability of the electronic device 1a can be improved.

In the present disclosure, the term "magnetic particle concentration" may refer to the volume occupied by the magnetic particles 134 (i.e., the total volume occupied by the plurality of magnetic particles 134) in a unit volume of the encapsulation layer 130. A greater volume occupied by the magnetic particles 134 in the unit volume indicates a higher magnetic particle concentration. In some embodiments, the unit volume may be, for example, 10000 cubic micrometers (μm³) or 1 cubic millimeter (mm³), but is not limited thereto. In other words, in the present disclosure, the term "magnetic particle concentration" may refer to the volume percentage of the magnetic particles 134 in the encapsulation layer 130, which may be calculated by the formula: A/a, where "A" is the volume occupied by the magnetic particles 134 in the unit volume of the encapsulation layer 130, and "a" is the unit volume of the encapsulation layer 130. The volume occupied by the magnetic particles 134 may be observed, for example, via a microscope. Alternatively, the magnetic particle concentration may be estimated by measuring the density of the encapsulation layer 130, the density of base material of the encapsulation layer 130, and the density of the magnetic particles 134. The unit volume of the encapsulation layer 130 may be, for example, the aforementioned 10000 μm³ or 1 mm³. In some embodiments, the magnetic particle concentrations may be compared based on the magnetic field strength induced by the magnetic particles 134 in an identical unit volume. For example, when the magnetic field strength induced by the magnetic particles 134 is stronger, the magnetic particles concentration is higher. The magnetic field strength may be detected, for example, using a gaussmeter, but is not limited thereto.

The encapsulation layer 130 covers a top surface and side surfaces of the light-emitting unit 120. Thereby, the encapsulation layer 130 can protect the light-emitting unit 120 and block moisture and/or oxygen from the external environment. Accordingly, the possibility of damage of the conductive structure or the internal portion of the light-emitting unit 120 caused by moisture and/or oxygen can be reduced. The encapsulation layer 130 may further include an encapsulation material 132, and the plurality of magnetic particles 134 are distributed in the encapsulation material 132. The volume occupied by the plurality of magnetic particles 134 in the encapsulation layer 130 may be greater than or equal to 0.1%. The method for calculating the volume occupied by the magnetic particles 134 in the encapsulation layer 130 may, for example, refer to relevant description of the aforementioned "magnetic particle concentration", but is not limited thereto. That is, in 100 volume parts of the encapsulation layer 130, the total volume occupied by the plurality of magnetic particles 134 may be greater than or equal to 0.1 volume parts, which may also be regarded as a volume percentage of the magnetic particles 134 in the encapsulation layer 130 being greater than or equal to 0.1%, but is not limited thereto. The proportion of the magnetic particles 134 in the encapsulation layer 130 may be adjusted according to the required light transmittance, magnetic force, and material properties. In some embodiments, the volume occupied by the plurality of magnetic particles 134 in the encapsulation layer 130 may range from 0.1% to 0.5%. Thereby, it is beneficial to reduce the influence of the magnetic particles 134 on the light transmittance of the encapsulation layer 130.

The encapsulation layer 130 has a thickness T1 in the normal direction of the substrate 110. The thickness T1 may be greater than or equal to 3 micrometers (μm) and less than or equal to 10 millimeters (mm). In some embodiments, the thickness T1 may be 250 μm, but is not limited thereto. The thickness T1 may be flexibly adjusted according to actual needs. The thickness T1 may be the distance from the bottom surface of the encapsulation layer 130 (i.e., the surface of the encapsulation layer 130 contacting the substrate 110) to the top surface of the encapsulation layer 130.

The encapsulation material 132 may include a transparent polymer, a non-transparent polymer, other suitable materials, or a combination thereof. For example, the encapsulation material 132 may include silicone or epoxy resin, but is not limited thereto. The material of the magnetic particles 134 may include a soft magnetic material, a hard magnetic material, or a combination thereof. The soft magnetic material may include ferrite, silicon steel, other suitable materials, or a combination thereof, but is not limited thereto. The hard magnetic material may include neodymium-iron-boron (NdFeB), aluminum-nickel-cobalt (AlNiCo), other suitable materials, or a combination thereof, but is not limited thereto. The ferrite and the silicon steel have high magnetic permeability, the NdFeB has high coercivity and high magnetic energy product, the AlNiCo has good corrosion resistance and high-temperature stability. Suitable magnetic particles 134 may be selected according to the required performance of the electronic device 1a. The particle size of each of the magnetic particles 134 may range from 1 μm to 500 μm. Thereby, it is beneficial to improve the distribution uniformity of the magnetic particles 134 in the encapsulation material 132. In some embodiments, the particle size of each of the magnetic particles 134 may range from 1 μm to 10 μm. Furthermore, the particle sizes of the plurality of magnetic particles 134 may be the same or different. The magnetic particles 134 may have any shape, and the shapes of the plurality of magnetic particles 134 may be the same or different. In some embodiments, the magnetic particles 134 may have a rod-like, spherical, or nearly spherical shape. Thereby, it is beneficial to form the encapsulation layer 130 by a coating process. The term "nearly spherical shape" may refer to a shape of the magnetic particle 134 that is close to a spherical shape but not perfectly spherical. For example, the magnetic particle 134 may include at least two radii with a difference of less than 10% therebetween. In this way, with the magnetic attraction between the magnetic particles 134 and the magnetic material in the substrate 110 or the magnetic layer 140, the fastening strength of the light-emitting units 120 on the substrate 110 can be improved, so that the durability and the reliability of the electronic device 1a can be improved.

The electronic device 1a may optionally further include a magnetic layer 140 disposed on a side of the substrate 110 away from the light-emitting unit 120. The material of the magnetic layer 140 may include a soft magnetic material, a hard magnetic material, or a combination thereof. For example, the magnetic layer 140 may include an iron sheet, a ferrite sheet, an NdFeB sheet or an AlNiCo sheet, but is not limited thereto. The magnetic layer 140 is configured to be magnetically attracted to the magnetic particles 134 in the encapsulation layer 130. Accordingly, in the normal direction of the substrate 110, the light-emitting units 120 and the substrate 110 are sandwiched between the encapsulation layer 130 and the magnetic layer 140. With the magnetic attraction between the magnetic particles 134 and the magnetic layer 140, the fastening strength of the light-emitting units 120 on the substrate 110 can be enhanced, so that the durability and the reliability of the electronic device 1a can be improved.

In some embodiments, both the magnetic layer 140 and the magnetic particles 134 are made of hard magnetic materials. The magnetic layer 140 and the magnetic particles 134 are arranged to face each other with opposite magnetic poles, thereby generating a magnetic attraction therebetween. For example, in the normal direction of the substrate 110, when the magnetic layer 140 is arranged to face the magnetic particles 134 with the N pole thereof, the magnetic particles 134 are arranged to face the magnetic layer 140 with the S poles thereof. In some embodiments, one of the magnetic layer 140 and the magnetic particles 134 is/are made of a hard magnetic material, and the other is/are made of a soft magnetic material. The magnetic field of the hard magnetic material can magnetize the soft magnetic material, such that the hard magnetic material and the soft magnetic material are attracted to each other via the magnetic force. The magnetic layer 140 has a thickness T2 in the normal direction of the substrate 110. The thickness T2 may be greater than or equal to 10 μm and less than or equal to 300 μm. In some embodiments, the thickness T2 may be 50 μm. However, the present disclosure is not limited thereto, and the thickness T2 may be adjusted flexibly according to actual requirements.

There is a spacing distance D1 between the encapsulation layer 130 and the magnetic layer 140 in the normal direction of the substrate 110. The spacing distance D1 may be greater than or equal to 25 μm and less than or equal to 500 μm. In some embodiments, the spacing distance D1 may be 150 μm, but is not limited thereto. The spacing distance D1 may be flexibly adjusted based on the concentration and the material of the magnetic particles 134 in the encapsulation layer 130 and the material of the magnetic layer 140, such that the magnetic force between the magnetic particles 134 and the magnetic layer 140 can meet the requirement.

The light-emitting units 120 are capable of emitting light. For example, the light-emitting units 120 may be light-emitting diodes (LEDs) or organic light-emitting diodes (OLEDs). In some embodiments, the wavelength of the light may range from 600 nanometers (nm) to 1000 nm, and the intensity of the light may range from 1 mW/cm² to 200 mW/cm². Thereby, the light emitted by the light-emitting unit 120 is advantageous for improving blood circulation, promoting metabolism, reducing inflammation, accelerating tissue repair, and stimulating collagen synthesis, thereby facilitating the application of the electronic device 1a as a phototherapy device. For example, the main body 10a of the electronic device 1a may serve as a phototherapy patch. During use, the surface 111 of the substrate 110, on which the light-emitting units 120 are disposed, faces the phototherapy portion. In some embodiments, the main body 10a may serve as a pain relief patch, which can relieve arthritis, muscle strain, inflammation, and promote recovery. In some embodiments, the main body 10a may serve as a cosmetic patch, such as a facial mask or an eye mask. When the main body 10a serves as a facial mask, it can be used for improving uneven skin tone, dullness and wrinkles, and promoting collagen production. When the main body 10a serves as an eye mask, it can be used for improving puffiness, dark circles, eye fatigue, fine lines, and sagging around the eyes.

The light emitted by the light-emitting units 120 may include red light and near-infrared light. Compared to the red light, the near-infrared light exhibits stronger penetration into deep tissues. Light of different wavelengths and energies may have different penetration depths and therapeutic effects. The wavelengths and energies of the light emitted by the plurality of light-emitting units 120 may be the same or different and may be adjusted according to the phototherapy application and the phototherapy portion suitable for the electronic device 1a. Furthermore, the plurality of light-emitting units 120 may be independently controlled, for example, via different driving components (e.g., thin film transistors (TFTs)) and/or different signals provided by the control member 20, such that the plurality of light-emitting units 120 can be independently turned on or off and can independently emit light of the same or different wavelengths and energies.

Herein, the number of the light-emitting units 120 is plural as an example, and the plurality of light-emitting units 120 may be arranged in an array. Herein, the plurality of light-emitting units 120 are arranged along the direction X to form nine horizontal rows and along the direction Y to form twelve vertical columns, but are not limited thereto. The number and the arrangement of the plurality of light-emitting units 120 may be flexibly adjusted according to actual needs, such as the applicable phototherapy applications. There may be a pitch between any two adjacent light-emitting units 120, such as the pitches PH1 and PH2. The pitch may be greater than or equal to 2 mm and less than or equal to 20 mm. For example, the pitch may be 2 mm, 5 mm, or 10 mm, but is not limited thereto. The plurality of pitches between the plurality of light-emitting units 120 may be independently the same or different. For example, in FIG. 1, the light-emitting units 120 are arranged at a lower density at the peripheral region of the substrate 110 and at a higher density at the central region of the substrate 110, and the pitch PH1 is greater than the pitch PH2, but the present disclosure is not limited thereto. In some embodiments, the plurality of pitches of the plurality of light-emitting units 120 may all be the same, or the light-emitting units 120 are arranged at a lower density at the central region of the substrate 110 (i.e., with a larger pitch) and at a higher density at the peripheral region of the substrate 110 (i.e., with a smaller pitch). Alternatively, the light-emitting units 120 may be arranged at a higher density in the region of the substrate 110 corresponding to the region of the phototherapy portion requiring enhancement, and the light-emitting units 120 may be arranged at a lower density in other regions of the substrate 110 corresponding to other regions of the phototherapy portion. The pitch may be measured, for example, as the distance from the center of one of two adjacent light-emitting units 120 to the center of the other one of the two adjacent light-emitting units 120, or the distance from the rightmost edge of one of two adjacent light-emitting units 120 to the rightmost edge of the other one of the two adjacent light-emitting units 120, or the distance from the leftmost edge of one of two adjacent light-emitting units 120 to the leftmost edge of the other one of the two adjacent light-emitting units 120.

The electronic device 1a may optionally further include other electronic components disposed on the surface 111 of the substrate 110, such as one or more sensing units 125. In FIG. 1, the number of the sensing units 125 is four, and the four sensing units 125 are disposed near the four corners of the surface 111. However, the present disclosure is not limited thereto. The number and the locations of the sensing units 125 may be adjusted according to actual needs. The sensing units 125 may be configured to detect physiological information of the phototherapy portion. For example, when the main body 10a is applied as a cosmetic patch, the sensing units 125 may detect conditions such as skin tone or wrinkle distribution of the phototherapy portion. The electronic device 1a may then control the plurality of light-emitting units 120 to turn on or off corresponding to different portions, and may control the wavelength and the energy of the light emitted by the plurality of light-emitting units 120 corresponding to different portions based on the detection results, thereby adjusting phototherapy parameters based on the conditions of different users. In the present disclosure, with the encapsulation layer 130 including the magnetic particles 134, the fastening strength of the sensing units 125 on the substrate 110 can also be enhanced. In other words, the electronic device 1a of the present disclosure is advantageous for enhancing the fastening strength of the electronic components disposed on the substrate 110. The electronic components are not limited to the light-emitting units 120. The types of the electronic components of the electronic device 1a are not limited to those described above and may be electronic components with various functions depending on product design requirements.

The substrate 110 may include a flexible substrate. The term "flexible" refers to being bendable, foldable, rollable, stretchable, or deformable in any manner, but is not limited thereto. Thereby, it is advantageous for the main body 10a being configured to be bendable, foldable, rollable, or stretchable. The substrate 110 may be configured to carry and/or support film layers and/or structures disposed thereon. In FIG. 2, the substrate 110 is a single-layer structure as an example, but is not limited thereto. In some embodiments, the substrate 110 may include a multilayer structure. For example, the substrate 110 may include a circuit layer and two insulating layers, and the two insulating layers may be respectively disposed above and below the circuit layer along the normal direction to provide insulation and protection for the circuit layer. In some embodiments, the substrate 110 may include a magnetic material. The circuit layer may include various wires, circuits, active components, and/or passive components applicable to the electronic device 1a. For example, the wires in the circuit layer may be electrically connected to the light-emitting units 120 to deliver current and/or electrical signals to the light-emitting units 120. The active components may include driving components, such as voltage regulators, current control components, thin-film transistors (TFTs) formed by thin-film processes, or metal-oxide-semiconductor field-effect transistors (MOSFETs) formed by semiconductor processes, for controlling brightness, switching, or pulse width modulation (PWM) dimming of the light-emitting units 120, but are not limited thereto. The substrate 110 may further include another insulating layer disposed on the insulating layer adjacent to the light-emitting units 120. A portion of each of the light-emitting units 120 may be embedded in the another insulating layer to enhance the fastening effect of the light-emitting units 120, thereby reducing the detachment or poor electrical connection due to external forces. The materials of the two insulating layers disposed above and below the circuit layer, for example, may include organic materials, other suitable materials, or a combination thereof, such as polyimide (PI), polycarbonate (PC), polyethylene terephthalate (PET), or a combination thereof, but are not limited thereto. The material of the another insulating layer may include acrylic, epoxy resin, resin, photoresist material, other suitable materials, or a combination thereof, but is not limited thereto. In some embodiments, the substrate 110 may be a flexible printed circuit (FPC), but is not limited thereto.

The electronic device 1a may optionally further include a contact layer 150 disposed on a side of the encapsulation layer 130 away from the substrate 110. When the electronic device 1a serves as a phototherapy device, the contact layer 150 may be configured to contact the phototherapy portion, such as human skin. The material of the contact layer 150 may include a transparent material. In some embodiments, the term "transparent material" refers to a material having a light transmittance of more than 90% for light with the wavelength ranging from 600 nm to 1000 nm, but is not limited thereto. The light emitted by the light-emitting units 120 can pass through the contact layer 150. The material of the contact layer 150 may include a skin-contact dressing. The material of skin-contact dressing may include a biocompatible material, a hydrogel material, a silicone material, other suitable materials, or a combination thereof, but is not limited thereto. In FIG. 1, in the top view direction (e.g., the direction Z) of the main body 10a (or the substrate 110), the contact layer 150 and the film layers disposed therebelow have the same area and are completely overlapped with each other in the top view direction. However, the present disclosure is not limited thereto. In some embodiments, in the top view direction of the main body 10a (or the substrate 110), the area of the contact layer 150 may differ from that of the film layers disposed therebelow. In some embodiments, the area of the contact layer 150 may cover the plurality of light-emitting units 120, but is not limited thereto.

The electronic device 1a may optionally further include a connecting layer 160. The connecting layer 160 is disposed between the substrate 110 and the magnetic layer 140 and is configured to connect the magnetic layer 140 to the substrate 110. The material of the connecting layer 160 may be selected according to the materials of the substrate 110 and the magnetic layer 140. For example, the material of the connecting layer 160 may include a silicone material, a polymer composite material, or the like. For example, the material of the connecting layer 160 may include silicone double-sided adhesive, thermoplastic polyurethane (TPU) hot melt adhesive film, acrylic double-sided adhesive, TPU mixed with a magnetic material, other suitable materials, or a combination thereof, but is not limited thereto.

The electronic device 1a may optionally further include a connecting layer 170. The connecting layer 170 is disposed between the encapsulation layer 130 and the contact layer 150 and is configured to connect the contact layer 150 to the encapsulation layer 130. The material of the connecting layer 170 may include a transparent material. In some embodiments, the term "transparent material" refers to a material having a light transmittance of more than 90% for light with the wavelength ranging from 600 nm to 1000 nm, but is not limited thereto. The light emitted by the light-emitting units 120 can pass through the connecting layer 170. The material of the connecting layer 170 may be selected according to the materials of the encapsulation layer 130 and the contact layer 150. For example, the material of the connecting layer 170 may include a silicone material, a polymer composite material, or the like. For example, the material of the connecting layer 170 may include silicone double-sided adhesive, thermoplastic polyurethane (TPU) hot melt adhesive film, acrylic double-sided adhesive, TPU mixed with a magnetic material, other suitable materials, or a combination thereof, but is not limited thereto. In some embodiments, the connecting layer 170 may be configured to be removable or releasably disposed on the encapsulation layer 130. When the electronic device 1a does not include the connecting layer 170, the contact layer 150 may also be configured to be removable or releasably disposed on the encapsulation layer 130. Accordingly, the contact layer 150 may be replaced as needed. The term "removable or releasably disposed" may refer to that, when the connecting layer 170 or the contact layer 150 is removed, the surface of the encapsulation layer 130 on which the connecting layer 170 or the contact layer 150 is disposed will not be, or will be substantially not, damaged, such that the electronic device 1a can remain functional after the contact layer 150 is replaced.

In FIG. 1, in the top view direction (e.g., the direction Z) of the main body 10a (or the substrate 110), the main body 10a is substantially rectangular or approximately rectangular. The shape of the main body 10a is mainly determined according to the shape of the substrate 110, and the shapes of the film layers disposed on the substrate 110 may correspond to that of the substrate 110. Herein, the shapes and areas of the encapsulation layer 130, the magnetic layer 140, and the contact layer 150 may all be the same as those of the substrate 110, and the encapsulation layer 130, the magnetic layer 140, the contact layer 150 and the substrate 110 may completely overlap in the top view direction of the main body 10a (or the substrate 110), but are not limited thereto. In some embodiments, the shapes of the film layers disposed on the substrate 110 may be the same as that of the substrate 110, and the areas of the film layers disposed on the substrate 110 may be may be slightly smaller than that of the substrate 110, such that in the top view direction of the main body 10a (or the substrate 110), all the film layers disposed on the substrate 110 fall within the outline of the substrate 110.

The electronic device 1a may optionally further include a control member 20. The control member 20 may optionally include a switch unit 210, an interface unit 220, and a display unit 230. The switch unit 210 is configured to control the turning-on and turning-off of the electronic device 1a. Herein, the switch unit 210 is a button as an example. The user may press the switch unit 210 to turn the electronic device 1a on or off. The interface unit 220 is configured to allow the user to input control signals. Herein, the interface unit 220 includes a button 222 and a button 224 as an example. For example, the user may press the button 222 to decrease the energy and/or operation time of the light emitted by the light-emitting units 120, and may press the button 224 to increase the energy and/or operation time of the light emitted by the light-emitting units 120. However, the present disclosure is not limited thereto. The display unit 230 is configured to display the operating status of the electronic device 1a. Herein, the display unit 230 is an indicator light as an example. For example, when the indicator light is on, it may indicate that the electronic device 1a is in an operating state. In some embodiments, the indicator light may emit light of different colors and/or flashing frequencies to represent different operating modes, such as a normal mode, an enhanced mode, etc., but the present disclosure is not limited thereto. The control member 20 may be configured with different units according to actual needs, and each unit may be configured in different forms. For example, in some embodiments, the control member 20 may be configured with a touch display panel, which may perform the functions of the interface unit 220 and the display unit 230, but the present disclosure is not limited thereto.

Although not shown in the drawings, the control member 20 may optionally further include a power unit and a control unit disposed inside the control member 20. The power unit is configured to supply power required for the operation of the electronic device 1a. The power unit may be a battery, such as a dry battery or a lithium battery. In some embodiments, the power unit may be a rechargeable battery. The control unit is configured to provide control signals to the electronic components (e.g., the light-emitting units 120) of the main body 10a. In some embodiments, the control unit may also be configured to receive, compute, and analyze signals emitted by the electronic components of the main body 10a, and provide control signals to the electronic components of the main body 10a based on the computation and analysis results. The control unit may have computing and analysis capabilities. For example, the control unit may include a central processing unit (CPU) or a microcontroller unit (MCU), but is not limited thereto.

The electronic device 1a may optionally further include a connecting member 30. The connecting member 30 is configured to electrically connect the main body 10a and the control member 20. For example, the connecting member 30 may transmit power from the power unit of the control member 20 to the electronic components (e.g., the light-emitting units 120) of the main body 10a. The connecting member 30 may also serve as a signal transmission path between the control unit of the control member 20 and the electronic components of the main body 10a. The connecting member 30 may be, for example, a transmission cable. The main body 10a and the control member 20 may respectively include connecting holes 112 and 212. Two ends of the connecting member 30 may be detachably installed in the connecting holes 112 and 212. Accordingly, the connecting member 30 may be electrically connected to the circuit layer in the substrate 110 through the connecting hole 112, and thereby electrically connected to the electronic components (e.g., the light-emitting units 120) on the substrate 110. The connecting member 30 may also be electrically connected to the circuit structure inside the control member 20 through the connecting hole 212, and thereby electrically connected to the control unit. In some embodiments, the main body 10a and the control member 20 may be electrically connected wirelessly. In this case, the connecting member 30, the connecting hole 112 and/or the connecting hole 212 may be omitted.

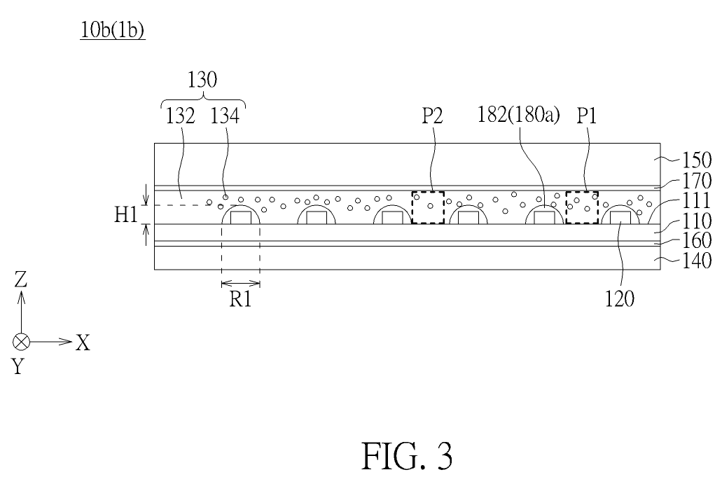

Please refer to FIG. 3, which is a partial cross-sectional schematic view of an electronic device 1b according to a second embodiment of the present disclosure. The viewing angle of FIG. 3 may be the same as that of FIG. 2. The electronic device 1b includes a main body 10b and may optionally include a control member (see the control member 20 in FIG. 1) and a connecting member (see the connecting member 30 in FIG. 1). The main difference between the main body 10b and the main body 10a is that the main body 10b may further include a plurality of encapsulation layers 180a. Each of the encapsulation layers 180a is disposed between one of the light-emitting units 120 and the encapsulation layer 130. The encapsulation layer 180a covers the top surface and side surfaces of the light-emitting unit 120. The plurality of encapsulation layers 180a encapsulate the plurality of light-emitting units in a one-to-one manner. Accordingly, the encapsulation layer 180a can provide further protection for the light-emitting units 120. In some embodiments, depending on the material of the magnetic particles 134, direct contact between the magnetic particles 134 and the light-emitting units 120 may affect the performance of the light-emitting units 120, such as causing a short circuit. With the encapsulation layer 180a, it is favorable for preventing direct contact between the magnetic particles 134 and the light-emitting units 120.

The encapsulation layer 180a may include an encapsulation material 182. For details about the encapsulation material 182, reference may be made to the description of the encapsulation material 132. The encapsulation materials 132 and 182 may be the same or different from each other. In some embodiments, the encapsulation layer 180a may be a transparent hemispherical encapsulation. The hemispherical encapsulation may have a diameter R1 and a height H1. The diameter R1, for example, may be the maximum length of the hemispherical encapsulation in the horizontal direction (e.g., the direction X), and the height H1 may be the maximum length of the hemispherical encapsulation in the normal direction of the substrate 110. The diameter R1, for example, may range from 300 μm to 2000 μm, and the height H1, for example, may range from 30 μm to 200 μm, but are not limited thereto. The dimension of the encapsulation layer 180a may be adjusted according to the size of the light-emitting unit 120. For other details of the electronic device 1b of the second embodiment, reference may be made to the relevant descriptions above.

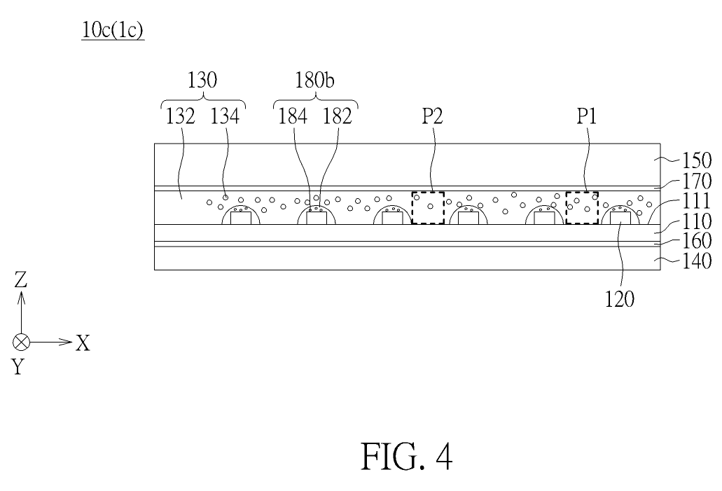

Please refer to FIG. 4, which is a partial cross-sectional schematic view of an electronic device 1c according to a third embodiment of the present disclosure. The viewing angle of FIG. 4 may be the same as that of FIG. 2. The electronic device 1c includes a main body 10c, and may optionally include a control member (see the control member 20 in FIG. 1) and a connecting member (see the connecting member 30 in FIG. 1). The main difference between the main body 10c and the main body 10b is that the encapsulation layer 180b may further include a plurality of magnetic particles 184. The plurality of magnetic particles 184 are distributed in the encapsulation material 182. The volume occupied by the plurality of magnetic particles 184 in the encapsulation layer 180b may be greater than or equal to 0.1% and less than or equal to 0.5%. In some embodiments, depending on the material of the magnetic particles 184, direct contact between the magnetic particles 184 and the light-emitting unit 120 may cause no effect or only a negligible effect. With the encapsulation layer 180b including the magnetic particles 184, it is advantageous for further enhancing the fastening strength of the light-emitting unit 120 on the substrate 110 via the magnetic force of the magnetic particles 184. Details about the magnetic particles 184, reference may be made to the relevant description of the magnetic particles 134. The magnetic particles 134 and 184 may be the same or different from each other. The concentration of the magnetic particles 184 in the encapsulation layer 180b and the concentration of the magnetic particles 134 in the encapsulation layer 130 may be the same or different from each other. For other details of the electronic device 1c of the third embodiment, reference may be made to the relevant descriptions above.

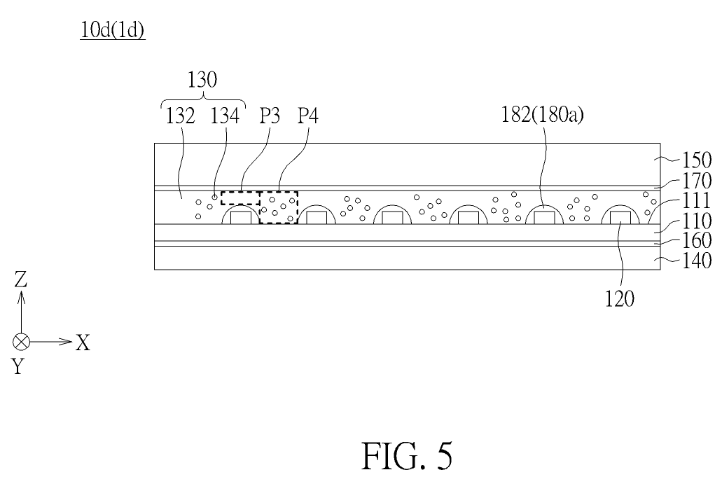

Please refer to FIG. 5, which is a partial cross-sectional schematic view of an electronic device 1d according to a fourth embodiment of the present disclosure. The viewing angle of FIG. 5 may be the same as that of FIG. 2. The electronic device 1d includes a main body 10d, and may optionally include a control member (see the control member 20 in FIG. 1) and a connecting member (see the connecting member 30 in FIG. 1). The main difference between the main body 10d and the main body 10b is the distribution of the magnetic particles 134 in the encapsulation layer 130. As shown in FIG. 5, the encapsulation layer 130 includes a portion P3 and a portion P4. The portion P3 overlaps the light-emitting unit 120 in the normal direction, while the portion P4 does not overlap the light-emitting unit 120 in the normal direction. The magnetic particle concentration of the portion P3 is different from that of the portion P4. Thereby, the electronic device 1d may have desired light transmittance in different regions according to actual needs.

The phrase "the portion P3 overlaps the light-emitting unit 120 in the normal direction" may refer to portion P3 being completely or partially overlapping the light-emitting unit 120 in the normal direction. The phrase "the portion P4 does not overlap the light-emitting unit 120 in the normal direction” may refer to the portion P4 being completely non-overlapping with the light-emitting unit 120 in the normal direction.

Specifically, in FIG. 5, the encapsulation layer 130 includes a plurality of portions P3 and a plurality of portions P4 arranged alternately along a horizontal direction. The portions P3 correspond to the light-emitting units 120, while the portions P4 do not correspond to the light-emitting units 120, and the magnetic particle concentration of the portions P3 is arranged to be lower than that of the portions P4. Thereby, it can prevent the portions P3 to have excessively high magnetic particle concentration to affect the light output efficiency of the light-emitting units 120. With the portions P4 having a higher magnetic particle concentration, the overall magnetic force provided by the encapsulation layer 130 can meet the requirement. In some embodiments, the magnetic particle concentration of the portions P3 may be zero, but is not limited thereto. For other details of the electronic device 1d of the fourth embodiment, reference may be made to the relevant descriptions above.

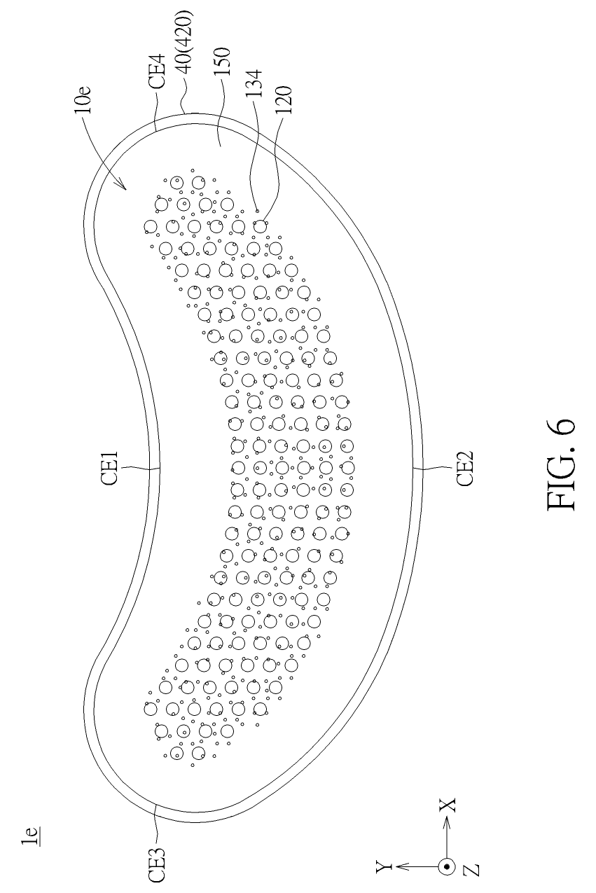

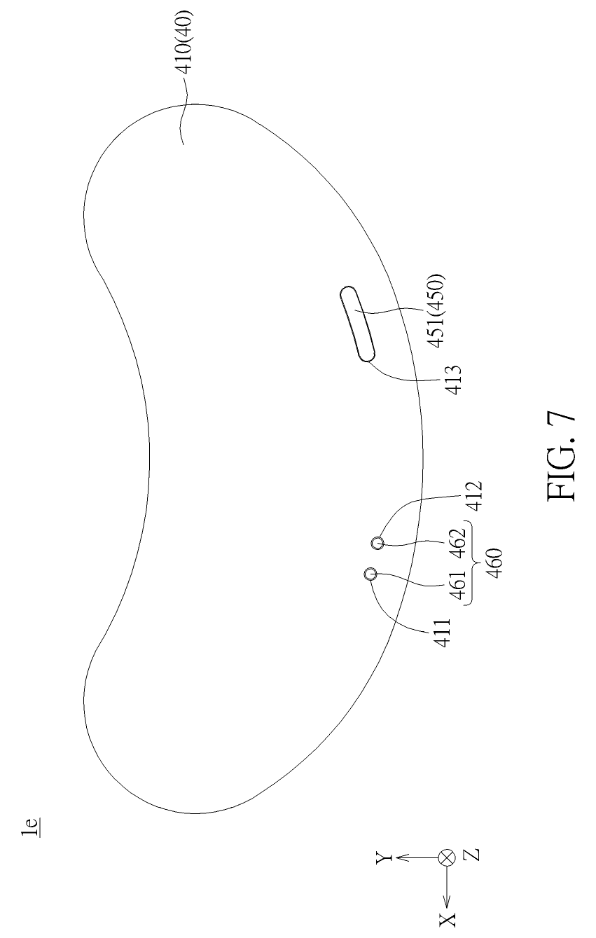

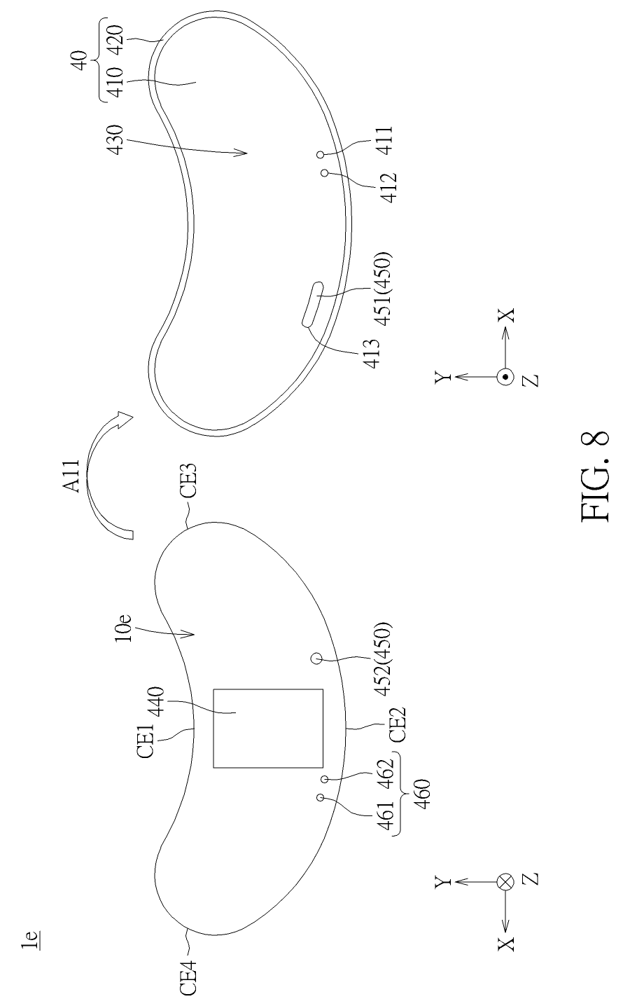

Please refer to FIGS. 6 to FIG. 8. FIG. 6 is a schematic top view of an electronic device 1e according to a fifth embodiment of the present disclosure. FIG. 7 is a schematic bottom view of the electronic device 1e shown in FIG. 6. FIG. 8 is an exploded schematic view of the electronic device 1e shown in FIG. 7. As indicated by arrow A11, FIG. 8 illustrates a housing 40 in FIG. 7 being moved along the normal direction of the substrate 110 and then rotated 180 degrees. Therefore, the inner side of the housing 40 in FIG. 7 faces in a direction into the plane of the paper, while the inner side of the housing 40 in FIG. 8 faces in a direction out of the plane of the page. The inner side of the housing 40 refers to the side of the housing 40 facing a main body 10e.

The electronic device 1e includes the main body 10e and the housing 40. The main body 10e is disposed in the housing 40. The main differences between the main body 10e and the main body 10a shown in FIG. 1 are as follows. The shape of the main body 10e is different from the shape of the main body 10a, and the number and the arrangement of the light-emitting units 120 of the main body 10e are different from the number and the arrangement of the light-emitting units 120 of the main body 10a. For details of the components (e.g., the substrate 110, the light-emitting unit 120, the encapsulation layer 130, the magnetic layer 140, etc.) of the main body 10e, reference may be made to the relevant descriptions above.

In FIG. 6, in the top view direction of the main body 10e (or the substrate 110), the shape of the main body 10e is approximately crescent-shaped and includes an arc-shaped contour. The arc-shaped contour includes an upper arc edge CE1, a lower arc edge CE2, a left arc edge CE3, and a right arc edge CE4. Each of the upper arc edge CE1 and the lower arc edge CE2 is approximately in the shape of a smile curve, and the left arc edge CE3 and the right arc edge CE4 are symmetrical to each other. The shape of the main body 10e may be configured to correspond to the phototherapy portion. The main body 10e may be flat or curved. For example, the electronic device 1e may be a phototherapy device applicable to human face, such as an eye phototherapy device. In this case, the main body 10e may be configured as a curved surface, which is favorable for the main body 10e conforming to the human face.

The housing 40 is disposed on the side of the substrate 110 away from the light-emitting unit 120, and is disposed outside the magnetic layer 140 (e.g., the magnetic layer 140 shown in FIGS. 2 to FIG. 4). The housing 40 includes a supporting portion 410 and an outer edge portion 420. The outer edge portion 420 surrounds the supporting portion 410 and has a protruding height relative to the supporting portion 410. The supporting portion 410 and the outer edge portion 420 together define an accommodation space 430, and the main body 10e is disposed in the accommodation space 430.

The electronic device 1e may further include a power unit 440, a switch unit 450, and a terminal unit 460. For details about the power unit 440, reference may be made to the relevant description of the power unit of the control member 20. The terminal unit 460 is configured to electrically connect the power unit 440 and an external power source (not shown), so that the external power source can supply power to the power unit 440. Herein, the terminal unit 460 includes terminals 461 and 462 as an example, the terminals 461 and 462 may respectively serve as a positive terminal and a negative terminal, but the present disclosure is not limited thereto. The switch unit 450 is configured to control the turning-on and turning-off of the electronic device 1e. Herein, the switch unit 450 includes a button 451 and a contact pad 452. The user may press the button 451 to control the contact pad 452 to form or break an electrical connection with the circuit layer in the substrate 110. The housing 40 is formed with holes 411 and 412 corresponding to the terminals 461 and 462, and the housing 40 is formed with a hole 413 corresponding to the switch unit 450. Thereby, the terminals 461, 462, and the button 451 may be exposed through the holes 411, 412, and 413, respectively, and are not covered by the housing 40. In the embodiment, the various components of the electronic device 1e are integrated as a single unit, without the need for a separate control member 20 and a separate connecting member 30, which is advantageous for simplifying the components of the electronic device 1e and enhancing the portability of the electronic device 1e.

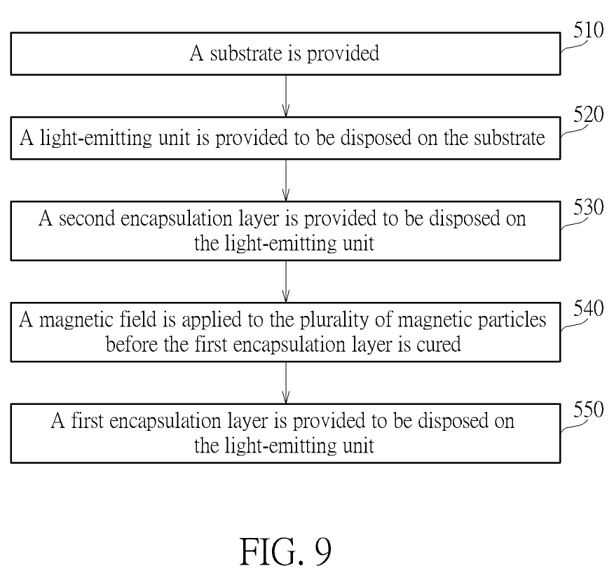

Please refer to FIG. 9, which is a flowchart illustrating steps of a method for manufacturing an electronic device according to one embodiment of the present disclosure. For the sake of convenience, the following description uses the electronic device 1a shown in FIGS. 1 and FIG. 2 as an example. The method for manufacturing the electronic device may include Steps 510, 520, and 550, and may optionally include Step 530 and/or Step 540.

In Step 510, a substrate 110 is provided, in which a surface 111 of the substrate 110 defines a normal direction. In Step 520, a light-emitting unit 120 is provided to be disposed on the substrate 110. In Step 550, a first encapsulation layer (i.e., the encapsulation layer 130) is provided to be disposed on the light-emitting unit 120. The first encapsulation layer (i.e., the encapsulation layer 130) includes a plurality of magnetic particles 134. The first encapsulation layer has different magnetic particle concentrations in a horizontal direction perpendicular to the normal direction. In Step 540, a magnetic field is applied to the plurality of magnetic particles 134 before the first encapsulation layer (i.e., the encapsulation layer 130) is cured.

Providing the first encapsulation layer (i.e., the encapsulation layer 130) to be disposed on the light-emitting unit 120 may include the following steps. First, a mixing step is performed, in which the plurality of magnetic particles 134 are mixed with the encapsulation material 132, so that the magnetic particles 134 are distributed in the encapsulation material 132 to form a mixed material. For example, a mixer may be used to perform the mixing step, and mixing time and speed may be adjusted according to the properties of the magnetic particles 134 and the encapsulation material 132 to improve the uniformity of the magnetic particles 134 in the encapsulation material 132.

Next, a defoaming step may optionally be performed to remove bubbles from the mixed material. For example, methods of vacuum treatment, heating treatment, ultrasonic treatment, or centrifugal treatment may be performed to allow the bubbles to escape from the mixed material or to allow the bubbles to burst and dissipate.

Next, an encapsulation step is performed, in which the mixed material is formed on the light-emitting units 120 by coating or injection, so that the mixed material covers the top surface and the side surfaces of the light-emitting units 120. After the mixed material is cured, the first encapsulation layer (i.e., the encapsulation layer 130) is obtained.

Before the first encapsulation layer (i.e., the encapsulation layer 130 or the mixed material) is cured, a magnetization step (i.e., Step 540) may optionally be performed. Specifically, when the magnetic particles 134 are made of a hard magnetic material, each magnetic particle 134 has independent magnetic poles, i.e., an N pole and an S pole. When the magnetic poles of the plurality of magnetic particles 134 are randomly oriented, the magnetic forces generated by the plurality of magnetic particles 134 may cancel each other out, thereby reducing the overall magnetic force of the plurality of magnetic particles 134. Therefore, when the magnetic particles 134 are made of hard magnetic materials, the magnetization step can be performed to align the magnetic poles of the plurality of magnetic particles 134 in an orderly manner, which is advantageous for enhancing the overall magnetic force of the magnetic particles 134.

During the magnetization step, a magnetic field may be applied to the plurality of magnetic particles 134. The magnetic field may be provided by a permanent magnet or an electromagnet. For example, the permanent magnet or the electromagnet may be placed above or below the light-emitting units 120 along the normal direction of the substrate 110. When the N pole of the permanent magnet or the electromagnet faces the plurality of magnetic particles 134, the magnetic particles 134 are influenced by the magnetic force to face the permanent magnet or the electromagnet with the S poles thereof. Similarly, when the S pole of the permanent magnet or the electromagnet faces the plurality of magnetic particles 134, the magnetic particles 134 are influenced by the magnetic force to face the permanent magnet or the electromagnet with the N poles thereof. Thereby, the magnetic particles 134 can have the same or substantially the same magnetic pole orientation. During the magnetization step, it is preferable to keep the position of the permanent magnet or the electromagnet fixed, so as to provide a stable magnetic field. In addition, the duration and temperature for applying the magnetic field may be adjusted according to the materials of the encapsulation material 132 and the magnetic particles 134. In some embodiments, the magnetic field may be applied to the plurality of magnetic particles 134 until the first encapsulation layer (i.e., the encapsulation layer 130) is completely cured.

When manufacturing the electronic device 1b shown in FIG. 3, the method for manufacturing the electronic device may further include Step 530, in which a second encapsulation layer (i.e., the encapsulation layer 180a) is provided to be disposed on the light-emitting unit 120. When manufacturing the electronic device 1c shown in FIG. 4, the second encapsulation layer in Step 530 may be replaced with the encapsulation layer 180b. Details of providing the encapsulation layer 180b may refer to the relevant description of providing the encapsulation layer 130 and are omitted herein. After the second encapsulation layer (i.e., the encapsulation layer 180a or 180b) is provided on the light-emitting unit 120, Step 550 is then performed to provide the first encapsulation layer (i.e., the encapsulation layer 130) on the second encapsulation layer.

When manufacturing the electronic device 1d shown in FIG. 5, in Step 550, two mixed materials with different magnetic particle concentrations may be prepared first. In the encapsulation step, the mixed material with a lower magnetic particle concentration may be formed by coating or injection at the positions corresponding to the portions P3, and the mixed material with a higher magnetic particle concentration may be formed by coating or injection at the positions corresponding to the portions P4. In this way, the portions P3 and P4 with different magnetic particle concentrations can be alternately arranged along the horizontal direction.

Compared to prior art, in the present disclosure, with the encapsulation layer including magnetic particles, it is beneficial to enhance the fastening strength of the electronic components (e.g., the light-emitting unit) on the substrate through the magnetic force of the magnetic particles, thereby improving the durability and the reliability of the electronic device. In some embodiments, with a magnetic layer being disposed on a side of the substrate away from the light-emitting unit, the substrate and the electronic components (e.g., the light-emitting unit) disposed thereon can be sandwiched between the encapsulation layer and the magnetic layer. With the magnetic attraction between the magnetic particles and the magnetic layer, the fastening strength of the electronic components (e.g., the light-emitting unit) on the substrate can be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate, wherein a surface of the substrate defines a normal direction;
a light-emitting unit disposed on the substrate; and
a first encapsulation layer disposed on the light-emitting unit,
wherein the first encapsulation layer comprises a plurality of first magnetic particles, and the first encapsulation layer has different magnetic particle concentrations in a horizontal direction perpendicular to the normal direction.

2. The electronic device of claim 1, wherein the light-emitting unit is capable of emitting light with a wavelength ranging from 600 nanometers to 1000 nanometers, and an intensity of the light ranges from 1 mW/cm² to 200 mW/cm².

3. The electronic device of claim 1, further comprising:
a magnetic layer disposed on a side of the substrate away from the light-emitting unit.

4. The electronic device of claim 1, wherein a volume occupied by the plurality of first magnetic particles in the first encapsulation layer ranges from 0.1% to 0.5%.

5. The electronic device of claim 1, wherein a particle size of each of the plurality of first magnetic particles ranges from 1 μm to 10 μm.

6. The electronic device of claim 1, further comprising:
a second encapsulation layer disposed between the light-emitting unit and the first encapsulation layer.

7. The electronic device of claim 6, wherein the second encapsulation layer covers a top surface and side surfaces of the light-emitting unit.

8. The electronic device of claim 6, wherein the electronic device comprises a plurality of the light-emitting units and a plurality of the second encapsulation layers, and the plurality of second encapsulation layers encapsulate the plurality of light-emitting units in a one-to-one manner.

9. The electronic device of claim 6, wherein the second encapsulation layer comprises a plurality of second magnetic particles.

10. The electronic device of claim 6, wherein the second encapsulation layer is made of an encapsulation material.

11. The electronic device of claim 1, wherein the first encapsulation layer comprises a first portion overlapping the light-emitting unit in the normal direction and a second portion not overlapping the light-emitting unit in the normal direction, and a magnetic particle concentration of the first portion is different from a magnetic particle concentration of the second portion.

12. The electronic device of claim 11, wherein the magnetic particle concentration of the first portion is lower than the magnetic particle concentration of the second portion.

13. The electronic device of claim 11, wherein the magnetic particle concentration of the first portion is zero.

14. The electronic device of claim 1, further comprising:
a contact layer disposed on a side of the first encapsulation layer away from the substrate.

15. The electronic device of claim 14, wherein the contact layer is removable or releasably disposed on the first encapsulation layer.

16. The electronic device of claim 1, wherein the electronic device comprises a plurality of the light-emitting units, two adjacent ones of the plurality of light-emitting units have a first pitch therebetween, another two adjacent ones of the plurality of light-emitting units have a second pitch therebetween, and the first pitch is different from the second pitch.

17. A method for manufacturing an electronic device, comprising:
providing a substrate, wherein a surface of the substrate defines a normal direction;
providing a light-emitting unit disposed on the substrate; and
providing a first encapsulation layer disposed on the light-emitting unit, wherein the first encapsulation layer comprises a plurality of magnetic particles, and the first encapsulation layer has different magnetic particle concentrations in a horizontal direction perpendicular to the normal direction.

18. The method of claim 17, further comprising:
applying a magnetic field to the plurality of magnetic particles before the first encapsulation layer is cured.

19. The method of claim 17, further comprising:
providing a magnetic layer disposed on a side of the substrate away from the light-emitting unit.

20. The method of claim 17, further comprising:
providing a second encapsulation layer disposed between the light-emitting unit and the first encapsulation layer.
